(19) United States
(12) Patent Application Publication
(10) Pub. No.: US 2006/0268514 A1
(43) Pub. Date: Nov. 30, 2006

(54) Mounting apparatus for fan

(75) Inventors: Chen-Lu Fan, Tu-Cheng (TW); Li-Ping Chen, Tu-Cheng (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/291,755

(22) Filed: Dec. 1, 2005

(30) Foreign Application Priority Data
May 29, 2005 (CN) 200520059318.3

(51) Int. Cl. H05K 7/20

(52) U.S. Cl. 361/695

(57) ABSTRACT

A mounting apparatus for a fan (10) includes a cabinet (30) for receiving the fan (10) and a bracket (50) for receiving the cabinet (30). The cabinet (30) includes a side wall (32) having an elastic member (36), and a securing portion (37) is formed on the elastic member (36). The bracket (50) defines an opening (531) for the securing portion (37) of the elastic member (36) engaging therein. Wherein when the elastic member is deflected inwardly, the securing portion of the elastic member disengage from the opening of the bracket. The cabinet with the fan can be easily removed from the bracket.

### BACKGROUND OF THE INVENTION

1. Field of the Invention

The present invention relates to a mounting apparatus, and more particularly to a fan mounting apparatus used in a computer or a server.

2. General Background

Electronic devices typically generate heat during operation due to the flow of electricity through electronic components housed within the device. Electronic components may be damaged if this heat is not removed. Generally, an electronic device uses a fan to produce a flow of air for cooling the electronic components. Conventionally, a fan is mounted in the electronic device by a plurality of screws passing through corresponding holes of the fan, making it difficult and time consuming to replace or remove the fan for repair. Many electronic systems, such as servers, produce a great deal of heat because of the large number of electronic components contained therein. So, more than one fan may be required for cooling the components efficiently. Thus requiring many screws to mount the fans to the electronic device, making the replacement and removal process more difficult.

Accordingly, what is needed is a mounting apparatus whereby fans can be more easily attached and removed from the electronic device enclosure.

### SUMMARY

A mounting apparatus for a fan includes a cabinet for receiving a fan and a bracket for receiving the cabinet. The cabinet includes a side wall having an elastic member, and a securing portion is formed on the elastic member. The bracket defines an opening for the securing portion of the elastic member engaging therein. Wherein when the elastic member is deflected inwardly, the securing portion of the elastic member disengage from the opening of the bracket. The cabinet with the fan can be easily removed from the bracket.

Other advantages and novel features will be drawn from the following detail description of preferred embodiment with attached drawings, in which:

### BRIEF DESCRIPTION OF THE DRAWINGS

FIG. 1 is an exploded isometric view of the preferred embodiment of a mounting apparatus for a fan;

FIG. 2 is an assembled view of a fan and a cabinet in FIG. 1; and

FIG. 3 is an assembled view of the mounting apparatus of FIG. 1.

### DETAILED DESCRIPTION OF THE EMBODIMENT

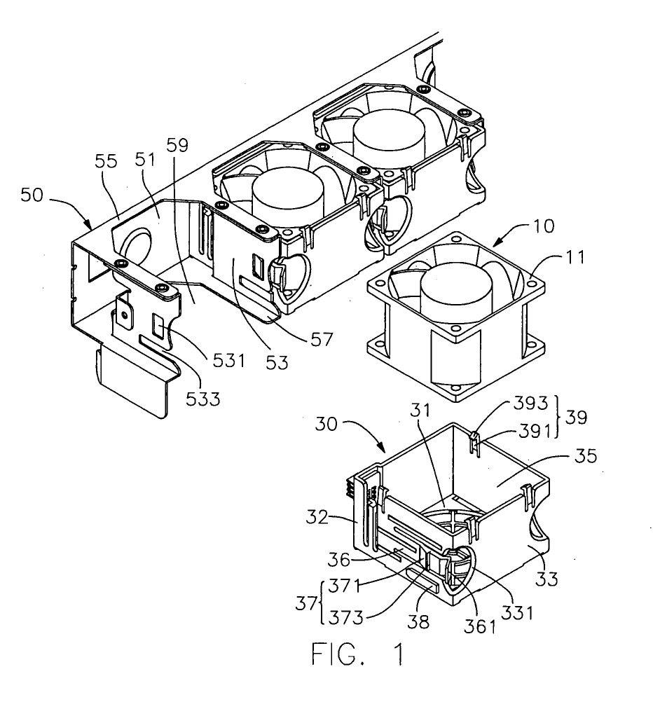

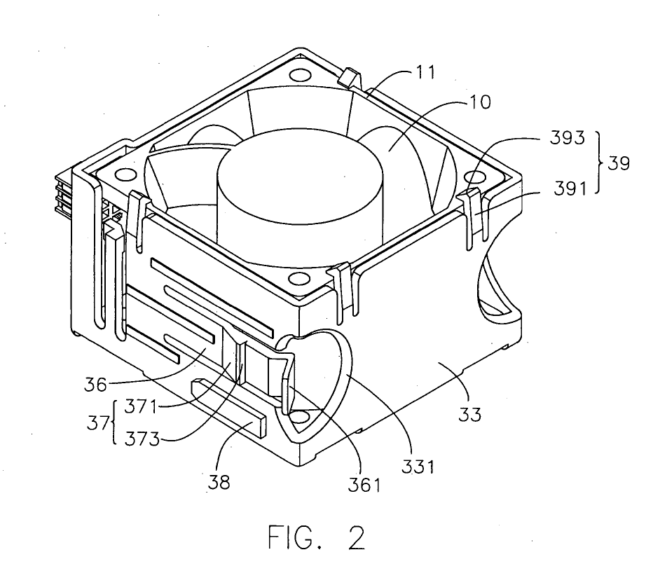

Referring to FIGS. 1 and 2, an apparatus for mounting a functional component like a fan 10 in a computer or other electronic devices includes a bracket 50 and at least a receiving cabinet 30 for accommodating the fan 10. In the present embodiment, the mounting apparatus is used for mounting a plurality of functional components like fans 10 in a chassis of the computer.

The receiving cabinet 30 includes a bottom wall 31, a pair of opposite side walls 32 perpendicular to the bottom wall 31 and another pair of side walls 33 adjacent to the side walls 32. A receiving housing 35 forming space therein for capturing a fan 10 is formed by the bottom wall 31 and the side walls 32, 33. A generally rectangular elastic member 36 is formed in one of the side walls 32. A generally wedge-shaped securing portion 37 protrudes from the elastic member 36 at a central section thereof. The securing portion 37 includes an inclined pressing plane 371 and a blocking plane 373 perpendicular to a surface of the elastic member 36. An action portion 361 extends outwardly from a distal end of the elastic member 36. An opening 331 is defined at a joint of the side wall 32 and the side wall 33 for providing a moving space to the action portion 361. A guiding protrusion 38 protrudes from the side wall 32 adjacent to the elastic member 36. A plurality of elastic hooks 39 is formed at the top edge of the side walls 32 and 33. Each of the elastic hooks 39 includes a cantilever 391 and a catch portion 393. A gap is defined between the cantilever 391 and the side wall 32 or 33 for providing elasticity to the cantilever 391.

The bracket 50 includes a back wall 51 and a plurality of spaced side walls 53 perpendicular to the back wall 51. A pair of flanges 55 and a pair of flanges 57 respectively extend from the back wall 51 and the side walls 53. A plurality of receiving housings 59 forming space therein for capturing the cabinets 30 is formed by the back wall 51, side walls 53, and the flanges 55, 57. An opening 531 is defined in each side wall 53 for the securing portion 37 engaging therein. A slot 533 is defined in each of the side walls 53 adjacent to the opening 531 for the guiding protrusion 38 sliding therein.

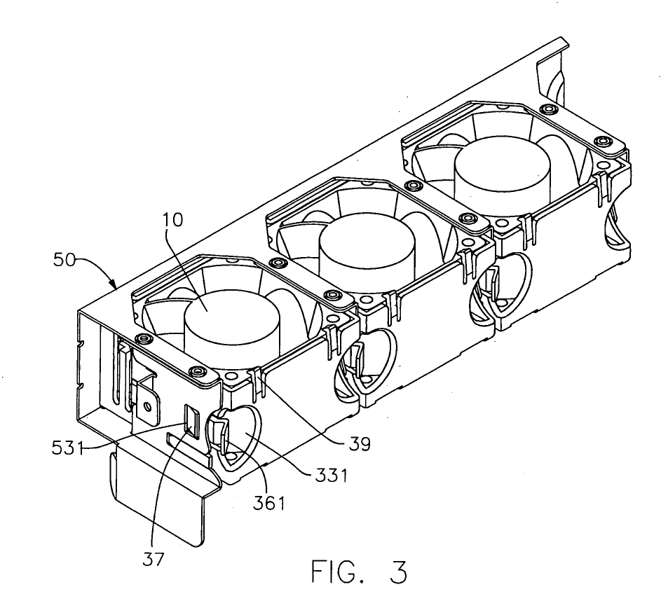

In assembly, the fan 10 is pushed into the cabinet 30 to form a fan module. The hooks 39 are forced to deform outwardly by a side edge of the fan 10. When the fan 10 is completely received in the receiving housing 35 of the cabinet 30, the hooks 39 rebound back to an initial state. A top 11 of the fan 10 is engaged by the catch portions 393 of the hooks 39 and the fan 10 is secured into the cabinet 30. Referring to FIG. 3, the fan module of the fan 10 and the cabinet 30 is inserted into the receiving housing 59 and the guiding block 37 of the cabinet 30 slides in the slot 531 of the side wall 53. The declined pressing plane 371 of the securing portion 37 is depressed by the side wall 53 of the bracket 50 to move the elastic member 36 inwardly until the securing portion 37 engages in the opening 531 completely, and the blocking plane 373 of the securing portion 37 is blocked by an upper edge of the opening 531. Thereby, the fan module cannot be accidentally withdrawn from the bracket 50. After a plurality of fan modules is secured into the bracket 50, the bracket 50 is mounted in a computer or a server enclosure (not shown).

To remove the fan 10 from the bracket 50, the action portion 361 of the elastic member is deflected inwardly to cause the securing portion 37 to disengage from the opening 531 of the bracket. Then the fan module is pulled out from the bracket 50.

It is to be understood, however, that even though numerous characteristics and advantages have been set forth in the foregoing description of a preferred embodiment, together with details of the structure and function, the disclosure is illustrative only, and changes may be made in detail, especially in matters of shape, size, and arrangement of parts within the principles of the invention to the full extent indicated by the broad general meaning of the terms in which the appended claims are expressed.

We claim:

1. A mounting apparatus for a fan, comprising:
a cabinet for receiving a fan, the cabinet comprising a side wall having an elastic member, a securing portion formed on the elastic member; and
a bracket for receiving at least a cabinet, the bracket defining an opening for the securing portion of the elastic member engaging therein.

2. The mounting apparatus for a fan as described in claim 1, wherein the securing portion of the elastic member comprises a declined pressing plane and a blocking plane perpendicular to the elastic member.

3. The mounting apparatus for a fan as described in claim 1, wherein an action portion is extended outwardly from a distal end of the elastic member.

4. The mounting apparatus for a fan as described in claim 3, wherein the cabinet further comprises an adjacent side wall, and an opening is defined at a joint of the two side walls for the action portion of the elastic member moving therein.

5. The mounting apparatus for a fan as described in claim 1, wherein a guiding block protrudes from the side wall of the cabinet, and a sliding slot is defined in the bracket for the guiding block sliding therein.

6. The mounting apparatus for a fan as described in claim 1, wherein the bracket comprises a back wall and a plurality of spaced side walls perpendicular to the back wall, and the opening is defined in the side wall of the bracket.

7. The mounting apparatus for a fan as described in claim 1, wherein the cabinet comprises a plurality of elastic hooks formed at the top edge of the cabinet for catching a top of the fan.

8. A mounting apparatus for a fan comprising:
a cabinet for receiving a fan, the cabinet comprising two pairs of side walls, a securing portion formed on one of the side walls, a plurality of hooks formed at top edges of the side walls for catching the fan; and
a bracket for capturing the cabinet, an opening defined in the bracket for the securing portion engaging therein.

9. The mounting apparatus for a fan as described in claim 8, wherein an elastic member is formed on the side wall of the cabinet, and the securing portion is formed on the elastic member.

10. The mounting apparatus for a fan as described in claim 9, wherein the securing portion comprises a declined pressing plane and a blocking plane perpendicular to a surface of the elastic member.

11. The mounting apparatus for a fan as described in claim 9, wherein an action portion extends from a distal end of the elastic member.

12. The mounting apparatus for a fan as described in claim 11, wherein an opening is defined at a joint of two adjacent side walls of the cabinet for the action portion of the elastic member moving therein.

13. The mounting apparatus for a fan as described in claim 8, wherein a guiding block protrudes from one of the side walls of the cabinet, and a sliding slot is defined in the bracket for the guiding block sliding therein.

14. The mounting apparatus for a fan as described in claim 8, wherein the bracket comprises a back wall and a plurality of spaced side walls perpendicular to the back wall, and the opening is defined in the side wall of the bracket.

15. The mounting apparatus for a fan as described in claim 14, wherein a pair of flanges respectively extends from the back wall and each side wall, and the back wall, the side walls, and the flanges together form a plurality of receiving housings.

16. An electronic device comprising:
at least one functional component of said electronic device;
a cabinet defining a first space for snugly receiving said at least one component therein; and
a bracket disposed in said electronic device for positioning more than one component of said electronic device including said at least one functional component therein, said bracket defining at least one second space for exclusively snugly receiving said cabinet therein, said cabinet capable of being positioned in said at least one second space when said cabinet completely moves into said at least one second space of said bracket.

17. The electronic device as described in claim 16, wherein a securing portion is formed on said cabinet and engagable with said bracket for positioning of said cabinet in said bracket.

18. The electronic device as described in claim 16, wherein a guiding protrusion is formed on said cabinet and engagable with said bracket so as to guide movement of said cabinet into and out of said at least one second space of said bracket.
